(19) United States
(12) Patent Application Publication
(10) Pub. No.: US 2010/0199577 A1
(43) Pub. Date: Aug. 12, 2010

(54) Cover for an object using solar radiation

(76) Inventor: Pieter Jan Sonneveld, Wageningen (NL)

Correspondence Address: ABELMAN, FRAYNE & SCHWAB, 666 THIRD AVENUE, 10TH FLOOR, NEW YORK, NY, 10017, US

(21) Appl. No.: 12/660,120

(22) Filed: Feb. 19, 2010

Related U.S. Application Data
(63) Continuation of application No. 10/585,678, filed on Jul. 7, 2006, now abandoned.

(30) Foreign Application Priority Data
Jan. 8, 2004 (NL) 1025191

(51) Int. Cl. E04D 13/18; B32B 3/00; H01L 31/00; A01G 9/00

(52) U.S. Cl. 52/173.3; 428/156; 136/256; 47/17

(57) ABSTRACT

A cover for an object using solar radiation includes a cover sheet made of a material transparent to solar radiation, wherein, viewed in cross-sectional view with respect to the sheet, the sheet has a zigzag profiled surface structure on either side. A combination of two covers has cover plates of each of the covers above one another, in particular running parallel to one another. Moreover, a combination of a cover and an object has the cover covering the object and the object uses, absorbs, and converts solar radiation.

### CROSS-REFERENCE TO RELATED APPLICATIONS

This application is a 371 of international application number PCT/NL2005/000009, filed on Jan. 10, 2005.

### BACKGROUND OF THE INVENTION

1. Field of the Invention

The invention relates to a cover for an object using solar radiation, the cover comprising a cover sheet of a material transparent to solar radiation.

2. Description of the Related Art

According to the invention “sheet”, such as in cover sheet, is understood in the broad sense as a flat, essentially two-dimensional object. If the thickness of the sheet is thin, the sheet can be of a membrane or film-like nature. If the thickness is thicker, the sheet can be of a plate-like nature; such a plate can be flexible but equally well rigid or something in between.

Such a cover is disclosed in DE 3,100,521, in which solar collectors are described. These solar collectors have a bottom part that absorbs solar radiation and a top part transparent to solar radiation as cover element. In the embodiment in FIG. 19, the transparent cover element is a zigzag corrugated plate and in the embodiment in FIG. 20 is a plate that has ribs on one side, specifically on the side facing the sun. The aim of both embodiments is to reduce the reflection of radiation incident from outside.

A disadvantage of the corrugated plate according to FIG. 19 of DE 3,100,521 is, inter alia, that the production of such a plate from glass is difficult, that such a plate made of plastic cannot readily be used in constructions that are subjected to higher temperatures, such as in the case of solar collectors, where the temperature of the cover material can easily exceed 150° C., and that a corrugated plate is relatively more difficult to fit and takes up space.

A disadvantage of the plate ribbed on one side according to FIG. 20 of DE 3,100,521 is that in practice this cover plate produces little or no reduction in reflection. Specifically, a degree of reflection takes place at the bottom surface facing away from the sun, which reflection has increased appreciably as a consequence of the ribbed top.

### BRIEF SUMMARY OF THE INVENTION

The aim of the present invention is to provide a cover element for an object using solar radiation, which cover element has an improved light transmission so that more solar radiation reaches said object, can be produced easily and can be fitted easily or can be incorporated in a further construction.

According to the invention light transmission is understood to mean the transmission of solar radiation, in particular of solar radiation in the range of visible light and near infrared heat radiation. According to the invention the wavelength range of the solar radiation to be transmitted can comprise the complete range from 300 nm.-3000 nm. or a portion of this range.

According to the invention “an object using solar radiation” is understood to be an object in the broad sense, which most certainly is also understood to include a body or a mass that utilizes solar radiation, for example generates electrical energy therefrom, extracts heat therefrom, performs or supports a chemical process, such as a photosynthesis, therewith, etc. For example, if the cover is used in the roof of a swimming pool, both the water in said swimming pool and also the surrounding floor of the swimming pool can be regarded as the object.

According to the invention the abovementioned aim is achieved in the broad sense by providing a cover for an object using solar radiation, wherein the cover comprises a cover sheet made of a material transparent to solar radiation, wherein, viewed in cross-sectional view with respect to the sheet, the sheet has a zigzag profiled surface structure on either side.

According to the invention the abovementioned aim is in particular achieved by providing a cover for an object using solar radiation, wherein the cover comprises a cover sheet made of a material transparent to solar radiation, wherein, viewed in cross-sectional view with respect to the sheet, the sheet has a zigzag profiled surface structure on either side, wherein the distance between two neighboring peaks of the zigzag surface structure is L and the thickness of the sheet is D and wherein L<D, in particular L<0.25 D.

Such a transparent sheet with a zigzag profile on both sides is simple to produce. In the case of plastic, embossing techniques known per se can be used for this. In the case of glass the zigzag profiled surface structure can be rolled directly into the sheet originating from the melt, by means of correspondingly profiled rolling rollers. Such a sheet with a zigzag profiled surface structure on both sides can easily be fitted and/or incorporated in a further construction just like ordinary glass plates. By means of such a sheet with a zigzag profiled surface structure on both sides it is possible to achieve a light transmission value which, depending on the type of material, can easily be 5 percentage points.

It is pointed out that the publications FR 2,832,811 and FR 2,530,787 both disclose a sheet with a surface structure in zigzag form, wherein in both cases L>D, at least insofar as these publications disclose anything in respect of L and D.

It is furthermore pointed out that insofar as U.S. Pat. No. 5,729,387 discloses a sheet with a zigzag structure on either side, this U.S. Pat. No. 5,729,387 does not disclose L<0.25 D.

In the case of the cover according to the invention it is advantageous if the flanks of the zigzag surface structure run at an angle β with respect to the plane of the sheet and wherein for the range of β:45°≦β≦85°, such as 45°≦β≦55°, applies. The lower limit of this range ensures that the portion of radiation incident perpendicularly on the cover sheet reflected from a flank is always reflected against a neighboring flank. The upper limit of this range is determined by production possibilities and the reduction in reflecting properties.

In this context it is furthermore advantageous according to the invention if β≦51° applies for the upper limit of the said β range. The reason for this is because the inventor has found that in the case of materials with an absorption coefficient, also called “power absorption coefficient”, having units m⁻¹, the light transmission starts to decrease substantially the further exceeds 51° from approximately 15 m⁻¹ in the case of diffuse incident solar radiation, as, for example, is the case in cloudy weather. The fall in the light transmission that has just been mentioned already starts to come into effect before β=51°. Furthermore, the inventor has found that the light transmission also starts to fall before β=51° in the case of solar radiation that is incident perpendicularly, which in contrast to the diffuse solar radiation is direct radiation, that is to say radiation directly incident on the cover. It is therefore preferable if β≦51° applies for the upper limit of the β range. The inventor has furthermore found that in the case of solar radiation incident perpendicularly on the cover sheet a substantial increase in the light transmission can be observed from β≈45° and that the steepness of this increase begins to decrease from β≈48°. It is therefore preferable if β≧48° applies for the lower limit of the β range. The inventor has furthermore found that, taking account of, on the one hand, diffuse solar radiation and, on the other hand, solar radiation incident perpendicularly, the optimum value for β is approximately 49°. It is therefore preferable according to the invention if for β:β=49°±2° applies. In this context it is in particular preferable if for β: β=49°±1° applies.

In the case of the cover according to the invention it is furthermore advantageous if the distance between two neighboring peaks of the zigzag surface structure is L and wherein for the range of L: 0.5 μm≦L≦2 mm applies. In the case of a zigzag surface structure with L values of up to 2 mm it is still easy, without the cover sheet becoming too thick, to achieve a thickness D of the cover sheet that is greater than the distance L between two neighboring peaks of the zigzag structure. Furthermore, the inventor has found that in the case of diffuse solar radiation although the light transmission decreases to some extent at very small L values, this is not significant as long as the wavelength of the solar radiation is taken as the minimum value for L. Taking into account that the wavelength range of visible light is between approximately 400 nm and 700 nm, the inventor then arrives at a lower limit for L of approximately 500 nm.

In order also to provide the cover sheet with self-cleaning properties, it is preferable according to the invention if the following is taken for the upper limit of the L range: L≦200 μm. If the cover sheet is of a membrane-like nature, the following will be taken for the upper limit of the L range: L≦100 μm. In the case of a cover sheet in the form of a 50 μm film, L could be, for example, 10 μm. For a more detailed indication, a few L values found to be optimum experimentally by the inventor are given in Table 1 below, depending on the type of cover sheet and typical thickness thereof.

TABLE 1
Optimum peak-peak distance of the zigzag structure

| | Typical material | Optimum peak-peak |
|---|---|---|
| | thickness D [mm] | distance L [mm] |
| Glass plate | 4-12 | 0.02-10, such as 0.02-2 |
| Plastic sheet | 1-6 | 0.01-8, such as 0.01-0.50 |
| and hollow- | | |
| core sheet | | |
| Film | 0.05-0.2 | 0.01-0.04 |

In general a smaller peak-peak distance is better for self-cleaning. Specifically, because dust particles are usually larger than 0.02 mm, the contact surface will be more restricted, as a result of which dust particles flush away more rapidly in a rain shower. The lower limit is usually determined by the method of production.

The inventor has furthermore found that with a view to the reduction in the light transmission a value of a few times the wavelength of the solar radiation to be transmitted can best be taken as minimum L value and also that the self-cleaning effect tends to decrease on reducing the L value further. Taking account of this, it is preferable to take the following as lower limit for the L range: L≧10 μm. With a view to, in particular, a good self-cleaning effect, it is preferable to take the following as the lower limit for the L range: L≧20 μm.

In the case of the cover according to the invention it is furthermore advantageous if the thickness of the sheet is D and if the range for D is: 20 μm≦D≦5 mm. In practice the D value will also be partly dependent on the type of material from which the cover sheet has been made. Specifically, this type of material, in combination with the available production techniques, will determine the lowest L value achievable. A larger L value implies a larger D value. A smaller L value makes a smaller D value possible. In the case of a 4 mm.-6 mm. glass plate, the minimum L value achievable will be, for example, 1 mm in the case of relatively simple production techniques. In the case of a film that is, for example, 50 μm thick, the L value could be, for example, 10 μm.

Although the zigzag structure can have the same value L on the one and the other side, the one side can also have a different L value to the other side.

With a view to the usual production techniques, it is furthermore advantageous in the case of the cover according to the invention if L<10 D, such as L<D. In this context it is in particular advantageous if L<0.25 D or even L<0.1 D.

In the case of the cover according to the invention it is furthermore advantageous if the flanks of the zigzag profiled surface structure that terminate at the same peak intersect one another at said peak. This prevents there being surfaces at the peaks that run approximately parallel to the plane of the sheet, which would cause the light transmission of the cover sheet as a whole to decrease. On corresponding grounds it is advantageous if the flanks that terminate in the same trough of the zigzag profiled surface structure intersect one another in that trough.

On the grounds of production considerations, it is advantageous if the zigzag surface structure comprises a multiplicity of grooves parallel to one another. Such a surface structure can be made relatively easily with high accuracy by feeding the cover sheet between two correspondingly grooved rolling rollers. In this case the grooves in the rolling rollers will preferably run in the peripheral direction of the rolling rollers.

In order to make the light transmission of the cover less sensitive to the incident direction of, in particular, direct solar radiation, it is advantageous according to the invention if the zigzag surface structure comprises a multiplicity of pyramid-shaped elevations. With this arrangement it is, in particular, advantageous if the base plane of each of the pyramid-shaped elevations runs in the direction in which the transparent sheet extends and wherein said base plane has a 3-, 4-, 6- or 8-cornered shape or comprises a combination of 4- and 8-cornered base planes. With this arrangement the base planes may or may not extend in one specific direction. The sensitivity to the incident direction will decrease as the number of corners of the base plane increases, but the increasing number of ribs between the flanks will cause, as a consequence of the fact that said ribs cannot be made completely sharp, such that rounding will be evident, the effective surface area of the cover available for trapping of solar radiation to increase. The optimum value for the number of corners will consequently be 2 or 3 corners. In order to optimize the effective surface area of the cover available for trapping of solar radiation, it is preferable if said 3-, 4-, 6- or 8-cornered base plane or said combination of 4- and 8-cornered base planes is shaped such that the pyramid-shaped elevations essentially fill the entire surface, or at least a surface zone, of the transparent sheet. With this arrangement it is not necessary that the pyramid-shaped elevations are entirely symmetrical. Additional light transmission is also achieved with elongated, on the other hand transformed, base planes or combinations of such structures.

According to the invention it is preferable if the cover sheet is a glass cover sheet, such as a cover sheet comprising silicon dioxide. The reason for this is because glass is able to withstand high temperatures and can readily be provided with a zigzag surface structure on both sides.

However, the cover sheet can also be made of a plastic, such as PMMA (polymethyl methacrylate), PC (polycarbonate) or PET-G (glycol-modified polyethylene terephthalate).

According to a further aspect the invention relates to a building, in particular a greenhouse for the cultivation of plants, provided with a roof comprising a cover according to the invention.

According to yet a further aspect the invention relates to a combination comprising a cover according to the invention and an object, wherein the cover covers the object and wherein the object uses, in particular absorbs, and converts solar radiation.

According to an advantageous embodiment of the combination according to the invention, the object comprises:

earth substrate and/or one or more plants; and/or

one or more solar cells of the type comprising semiconductor material, wherein the one or more solar cells are optionally placed in contact with one side of the cover sheet, for example applied to the cover sheet by deposition, such as vapor deposition, sputtering, chemical vapor deposition (CVD) or physical vapor deposition (PVD); and/or

a solar collector.

### BRIEF DESCRIPTION OF THE SEVERAL VIEWS OF THE DRAWINGS

The present invention will be explained in more detail below with reference to the figures. In the figures:

FIG. 1 shows a cross-sectional view of a cover sheet forming part of a cover according to the invention;

FIG. 2 shows, diagrammatically and in perspective, a zigzag profiled surface structure of pyramid-shaped elevations with a square base plane; and

FIG. 3 shows, diagrammatically and in perspective, a zigzag profiled surface structure of pyramid-shaped elevations (FIG. 3a) and depressions (FIG. 3b) with a uniform hexagonal base plane;

FIG. 4 shows a diagrammatic, perspective view of a zigzag profiled surface structure made up of a multiplicity of grooves parallel to one another;

FIG. 5a shows, diagrammatically and in perspective, a solar boiler provided with a curved cover according to the invention;

FIG. 5b shows, diagrammatically in section, a combination of a cover according to the invention with a vapor-deposited layer of solar cell material;

FIG. 5c shows, highly diagrammatically and in perspective, a greenhouse for the cultivation of plants provided with a cover according to the invention;

FIG. 6 shows a diagrammatic sectional view of a double-walled panel provided with a cover according to the invention;

FIG. 7 shows a graph showing, on the ordinate, light transmission and, on the abscissa, the zigzag angle β for perpendicular, direct incidence of the solar radiation;

FIG. 8 shows a graph corresponding to FIG. 7, but now for diffuse solar radiation; and

FIG. 9 shows a graph with the light transmission on the ordinate and the distance between the peaks of the zigzag shape on the abscissa.

### DETAILED DESCRIPTION OF THE INVENTION

The present invention is related to international application number PCT/NL2005/000009, filed on Jan. 10, 2005, which is incorporated herein by reference in its entirety.

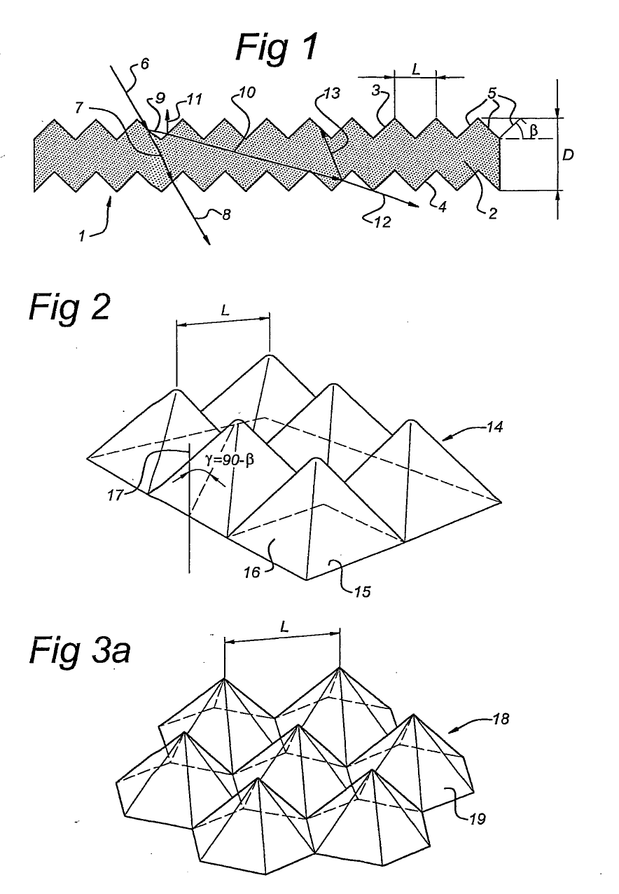

FIG. 1 shows a cross-sectional view of a cover sheet 1 for a cover according to the invention. The cover sheet 1 is made of material 2 that is transparent to solar radiation, such as glass or polycarbonate. The sheet 1 is provided with a surface structure on opposing sides 3 and 4. As can be seen, this surface structure 3, 4 has a zigzag profile on each side. The distance between adjacent peaks of the zigzag shape is indicated by L. And the angle at which the flanks 5 of the zigzag shape run with respect to the horizontal is indicated by β. The thickness of the sheet 1 is indicated by D.

Reference numeral 6 indicates an incident ray of light. This incident ray of light 6 is incident on a right-facing flank 5. On this incidence a portion of the ray of light 6 is introduced as ray of light 7 into the transparent material 2 and subsequently leaves the transparent material 2 at the bottom as ray of light 8. Another portion of the incident ray of light 6 is reflected as ray 9 that passes to the opposing, left-facing flank. At this left-facing flank the major proportion of the ray of light 9 is introduced into the material 2 as ray of light 10 and a small proportion is reflected back into the surroundings as ray of light 11. When it reaches the bottom of the sheet 1a major proportion of the ray of light 10 leaves the sheet 1 as ray of light 12 and a smaller proportion in the form of ray of light 13 is reflected upwards as ray of light 13. A large proportion of this ray of light 13 will again be guided downwards as internal reflection and a small proportion will be able to leave the sheet 1 at the top. It can thus be seen that a very large proportion of the incident ray of light 6 emerges from the sheet 1 at the bottom. The right-facing flanks 5 and the left-facing flanks 5 slope at the same angle β with respect to the longitudinal plane of the sheet.

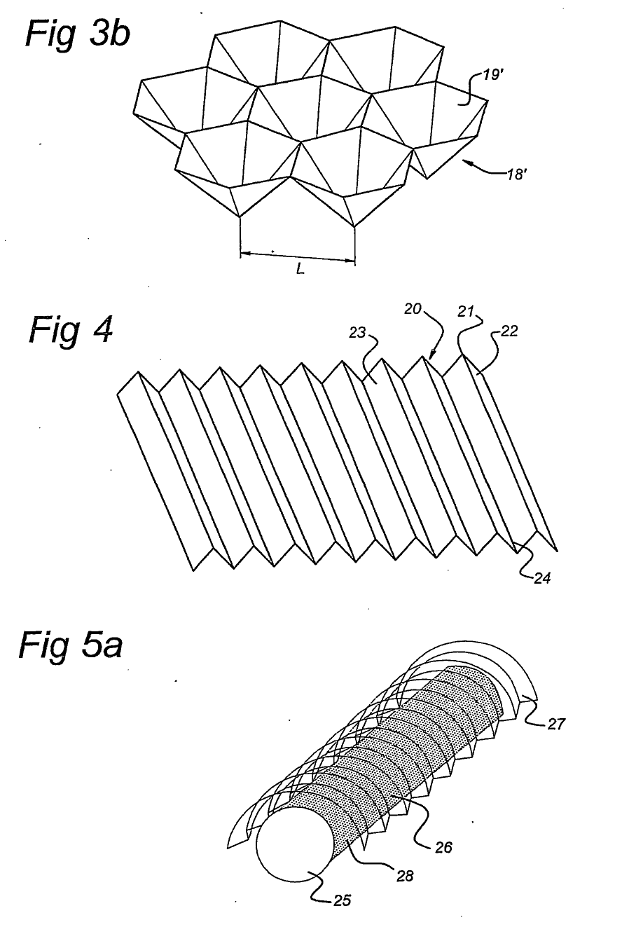

FIG. 2 shows, in perspective, the example of a pyramid-shaped surface structure. The underlying body of the sheet 1 is not shown in the figure and the surface structure at the bottom of said sheet is also not shown. Just like FIG. 3, FIG. 2 shows only the surface structure.

As can be seen in FIG. 2, here the surface structure is made up of pyramid-shaped elevations 14, each with a square base plane 15. However, it is pointed out that the base plane can also be non-square, rectangular or diamond-shaped. Here each pyramid-shaped elevation 14 has four side flanks 16. Each side flank 16 runs at the same angle γ with respect to a perpendicular 17. For the angle γ:γ=90°−β applies. This as such, again corresponds to the β in FIG. 1. The distance between the peaks of the pyramids is indicated by L, just as in FIG. 1. It will be clear to a person skilled in the art that if the surface structure in FIG. 2 is viewed in section, this then appears as is shown in FIG. 1.

FIG. 3a shows a further pyramid-shaped surface structure. The difference compared with the surface structure in FIG. 2 is that here 18 have a hexagonal base plane 19. Here again, the distance between the peaks of two adjacent pyramid-shaped elevations 18 is also indicated by L. What applies in respect of the angle γ or, alternatively, β in FIG. 3 is the same as in FIG. 2, although these angles are not shown in FIG. 3. It will be clear that the base plane can also have a different shape, such as a shape with more or fewer corners or an irregular shape.

FIG. 3b shows an example of a reversed pyramid-shaped surface structure. The difference compared with the surface structure in FIG. 3a is that instead of pyramid-shaped elevations with a hexagonal base plane, pyramid-shaped depressions 18′ with a hexagonal base plane 19′ have been made in the surface. Here again the distance between the peaks, located downwards, of two adjacent pyramid-shaped depressions 18 is also indicated by L. What applies in respect of the angle γ or, alternatively, β in FIG. 3 is the same as in FIG. 2, although these angles are not shown in FIG. 3b.

FIG. 4 shows, diagrammatically and in perspective, a grooved, zigzag surface structure of a cover sheet according to the invention. Here there is a multiplicity of grooves 20 which are parallel to one another and are each flanked by a right side flank 23 and a left side flank 22. Left 22 and right 23 side flanks in each case meet at the top at a peak 21 and at the bottom in a trough 24. It will be clear to a person skilled in the art that, if a cover sheet is provided on either side with a surface structure as shown in FIG. 4, the cross-sectional view of such a cover sheet then corresponds to what has been shown in FIG. 1.

It will furthermore be clear that a cover sheet according to the invention can be provided on the one side with a different type of zigzag profiled surface structure than on the other side. For example, the zigzag surface structure from FIG. 2 can be used on one side, while the zigzag surface structure from FIG. 4 can be used on the other side. It is also conceivable to use a surface structure as shown in FIG. 4 on either side, but with this arrangement to make the angle β and/or the peak-to-peak distance L per side different from one another.

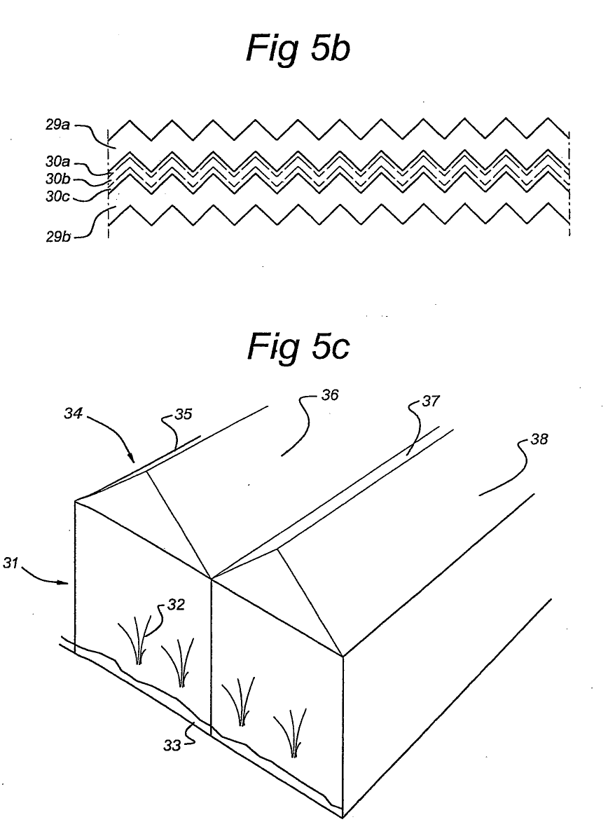

FIG. 5a shows, highly diagrammatically, a solar collector in the form of a solar boiler 25. Here the solar boiler 25 consists of a body, the surface 28 of which is in particular so designed that this absorbs heat from the solar energy in order to be able to heat liquid contained in the body. So as far as possible to prevent cooling of the solar boiler and also to protect the solar boiler against the effects of weather, an arc-shaped curved cover sheet 26 according to the invention is provided over this cylindrical solar boiler. This arc-shaped cover sheet 26 is provided with a grooved surface structure 27 running in the direction of the arc. In FIG. 5a this surface structure is shown as very rough for the purposes of illustration and also the transparent cover sheet 26 is shown diagrammatically in such a way that the surface structure of the inside and the surface structure of the outside are indistinguishable from one another. However, what is shown by this diagrammatic figure will be clear to a person skilled in the art.

FIG. 5b shows a combination according to the invention consisting of a transparent cover sheet 29a, which has a surface structure on either side, for example in accordance with FIG. 2 or in accordance with FIG. 4. A solar cell structure, consisting of a transparent electrically conducting layer, such as zinc oxide (ZnO) or indium tin oxide (ITO), negatively doped semiconductor material 30a, intrinsic semiconductor material 30b and positively doped semiconductor material 30c has been applied to the underside of the transparent cover sheet 29a by, for example, vapor deposition and/or CVD and/or PVD. A layer that is as far as possible light-reflecting and electrically conducting, such as aluminum or silver, is then applied, after which sealing is possible using the same sort of transparent cover sheet 29b as 29a positioned at the top. The cover 29b can be a zigzag-shaped aluminum sheet, but it is also possible to use steel with a reflective coating for this. The said semiconductor material 30a, b, c is typically silicon (Si), a mixture of silicon and germanium (SiGe), CuInSe₃ (CIS) or another solar cell structure. In the first case the semiconductor material consists of a structure of three layers, i.e. n-Si/i-Si/p-Si, where the n and p represent a negatively or positively doped material. Incidentally, it is also possible to make up the cell in reverse order, i.e. a p-Si/i-Si/n-Si structure, or by growing the cell in reverse order i.e. starting with growth on the zigzag bottom sheet 29b.

FIG. 5c shows, highly diagrammatically, a greenhouse 31 for the cultivation of plants 32. Earth substrate 33, in which the plants 32 grow, is also present in the greenhouse. The greenhouse has a roof 34. In this case this roof is made up of a multiplicity of roof panels 35, 36, 37 and 38 running in zigzag form. With this arrangement each panel is made up of one or more cover sheets according to the invention. These will be, for example, cover sheets with a surface structure as shown in FIG. 4 and a sectional shape as shown in FIG. 1. Panel 35 is thus as it were equated to transparent cover sheet 1. However, the surface structure of the panels 35, 36, 37 and 38 can also very well be in accordance with FIG. 2 and/or FIG. 3 on either side. A greenhouse 31 with a roof 34 provided with cover plates according to the invention has the major advantage that the light yield as a consequence of solar radiation in the interior of the greenhouse 1 is significantly greater than in the case of conventional greenhouses. If a film with a zigzag surface structure on either side is considered as cover sheet according to the invention, it will then be possible to make a so-called polytunnel using such a film. A polytunnel is usually made up of arc-shaped frames over which a film is stretched. A polytunnel therefore has an arc-shape, usually a semicircular arc-shape.

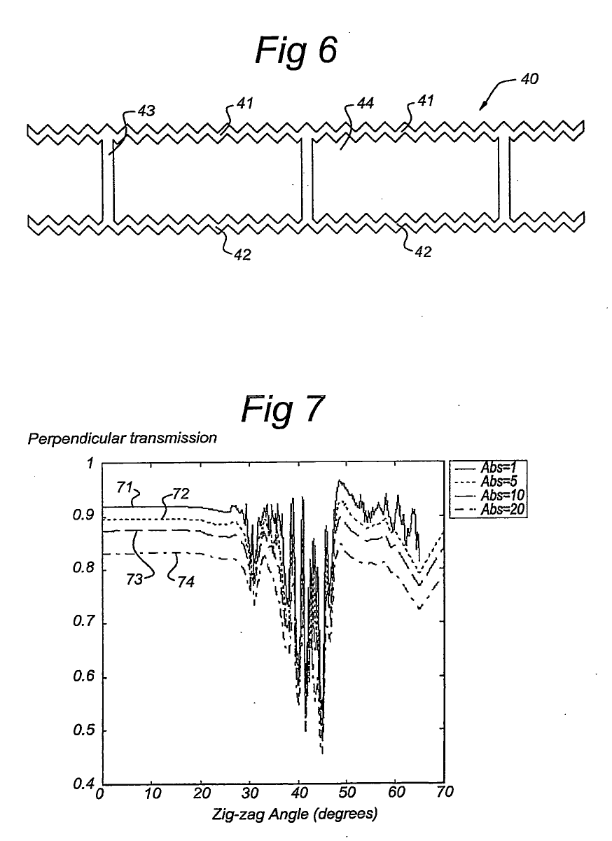

FIG. 6 shows, highly diagrammatically in cross-section, a hollow-core panel 40 made up with, in each case, segments 41 at the top, segments 42 at the bottom, which as such are made as a cover sheet according to the invention. Partitions 43 are also provided to form the channels. A gas can be present in the channels 44. The panel 40 thus provides an insulating effect. It is also possible to pass a gas that has to be heated under the influence of the solar heat through the channels 44. Furthermore, it is also possible to pass a liquid that has to be heated by solar heat through the channels 44. A panel construction as shown in FIG. 6 can also very readily be used as an insulated, transparent roof.

FIG. 7 shows a graph with the light transmission as unitless coefficient on the ordinate and the zigzag angle β in degrees on the abscissa. The results shown in FIG. 7 were obtained with cover plates constructed in accordance with FIG. 1 in combination with FIG. 4. The cover plates were made of glass and the thickness of the plates was 5 mm with a distance L between the peaks of 1 mm. The line 71 gives results for a glass plate for which the light absorption (ABS) is 1, the line 72 for a glass plate for which the ABS value is 5, corresponding to the absorption value of current glass, the line 73 shows the measurements for a glass plate with ABS value 10 and the line 74 shows the measurements for a glass plate with an ABS value 20. The light absorption value (ABS) here is the so-called “power absorption coefficient” with units m⁻¹. Furthermore, the results here are the results for sunlight with a wavelength of 550 nm incident perpendicularly on the plane of the plate.

In FIG. 7 it can be seen that the light transmission at angles of 0 to 25° is essentially constant. At approximately 25° to approximately 45° the light transmission has a jagged pattern, with severe drops in the transmission in places. Above approximately 45° a rise in the light transmission is observed. Above approximately 46° the increase in the light transmission compared with the light transmission value in the range from 0° to 25° is significant. The maximum light transmission is at 49°. The same effect arises at the various ABS values. At larger angles the light transmission decreases.

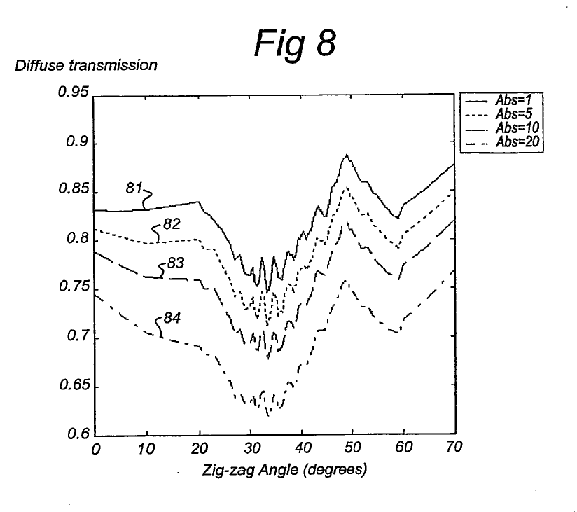

FIG. 8 shows results on the same plates as in FIG. 7, but now with diffuse incident light. It can be seen in this figure that the light transmission coefficient from 0° to, in any event, 22° is approximately constant for ABS=1 and that at higher ABS values the light transmission decreases with increasing angles. The light transmission decreases further at angles between 22° and 40°. For angles greater than 40° the light transmission increases to a maximum at 49°. There is then a fall to a low point at 60°, after which a rise again occurs.

In FIG. 8 line 81 shows measurements on 5 mm thick glass plates with a distance L between the peaks of 1 mm and an ABS value 0, line 82 measurements on corresponding glass plates with an ABS value 5, line 83 measurements on corresponding glass plates with an ABS value 10 and line 84 measurements on corresponding glass plates with an ABS value 20.

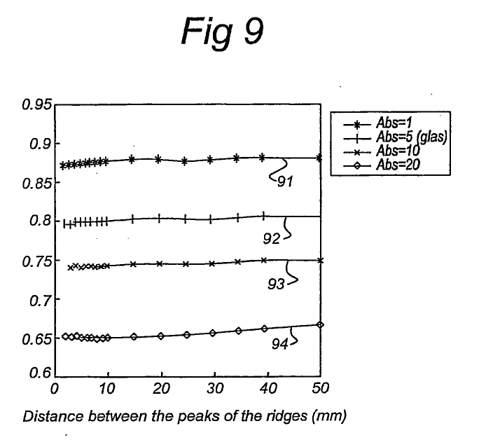

FIG. 9 shows, in a graph, measurements on various plates of 5 mm thick polycarbonate for diffuse incident light and a zigzag angle of 50°. Once again the light transmission coefficient is shown on the vertical axis. Here the distance L between the peaks of the ridges is in each case shown along the horizontal axis. Line 91 relates to measurements on a polycarbonate plate with an ABS value 0, line 92 relates to measurements on a polycarbonate plate with an ABS value 5, line 93 relates to measurements on a polycarbonate plate with an ABS value 10 and line 94 relates to measurements on a polycarbonate plate with an ABS value 20. Here the measurements concerned are again measurements on a sheet with a surface structure according to FIG. 4 in combination with FIG. 1 on either side. As is clear, here the depth of the grooves can be calculated on the basis of the distance L and the zigzag angle of 50°. It can be observed that the light transmission in the case of diffuse incident light is essentially independent of the distance between the peaks of the ridges. A slight decrease in the light transmission for diffuse light can apparently be observed with very small ridge-to-ridge distances and lower ABS values.

While the preferred embodiment of the present invention has been shown and described herein, it will be obvious that such embodiment is provided by way of example only. Numerous variations, changes and substitutions will occur to those skilled in the art without departing from the invention herein. Accordingly, it is intended that the invention be limited only by the spirit and scope of the appended claims.

1. Cover for an object using solar radiation, wherein the cover comprises: a cover sheet made of a material transparent to solar radiation; wherein, viewed in cross-sectional view with respect to the sheet, the sheet has a zigzag profiled surface structure on either side; and wherein the distance between two neighboring peaks of the zigzag surface structure is L and the thickness of the sheet is D; and wherein L<0.25 D.

2. Cover according to claim 1, wherein the flanks of the zigzag surface structure run at an angle β with respect to the plane of the sheet; and wherein for the range of β:β is greater than or equal to 45° and is less than or equal to 85°.

3. Cover according to claim 2, wherein β is less than or equal to 51°.

4. Cover according to claim 2, wherein β is greater than or equal to 47°.

5. Cover according to claim 2, wherein β=49°±2°.

6. Cover according to claim 2, wherein β=49°±1°.

7. Cover according to claim 1, wherein the distance between two neighboring peaks of the zigzag surface structure is L; and wherein for the range of L:L is greater than or equal to 0.5 μm and is less than or equal to 8 mm.

8. Cover according to claim 7, wherein L is less than or equal to 200 μm.

9. Cover according to claim 7, wherein L is less than or equal to 100 μm.

10. Cover according to claim 7, wherein L is less than or equal to 50 μm.

11. Cover according to claim 7, wherein L is greater than or equal to 10 μm.

12. Cover according to claim 7, wherein L is greater than or equal to 20 μm.

13. Cover according to claim 7, wherein the zigzag surface structure has a different value for L on the one side than the other side.

14. Cover according to claim 1, wherein the thickness of the sheet is D; and wherein D is greater than or equal to 20 μm and is less than or equal to 12 mm.

15. Cover according to claim 7, wherein L<0.1 D.

16. Cover according to claim 1, wherein the flanks of the zigzag profiled surface structure that terminate at the same peak intersect one another at said peak.

17. Cover according to claim 1, wherein the zigzag surface structure includes a multiplicity of grooves parallel to one another.

18. Cover according to claim 1, wherein the zigzag surface structure includes a multiplicity of pyramid-shaped elevations.

19. Cover according to claim 18, wherein the base plane of each of the pyramid-shaped elevations or depressions runs in the direction in which the transparent sheet extends; and wherein said base plane has a 3-cornered, 4-cornered, 6-cornered, or 8-cornered shape or includes a combination of 4-cornered and 8-cornered base planes.

20. Cover according to claim 19, wherein the 3-cornered, 4-cornered, 6-cornered, or 8-cornered base plane or the combination of 4-cornered and 8-cornered base planes is shaped such that the pyramid-shaped elevations or, alternatively, depressions essentially fill the entire surface, or at least a surface zone, of the transparent sheet.

21. Cover according to claim 1, wherein the cover sheet is flat or at least contains flat segments.

22. Cover according to claim 1, wherein the cover sheet is at least partially curved.

23. Cover according to claim 22, wherein the curvature is arc-shaped; and wherein said curvature preferably extends over 150° to 180°.

24. Cover according to claim 1, wherein the cover sheet, or at least segments thereof, is arranged at an angle and wherein the zigzag surface structure is made such that this drains along the slope.

25. Cover according to claim 1, wherein the cover sheet is a glass cover sheet containing silicon dioxide.

26. Cover according to claim 1, wherein the cover sheet is made of a plastic selected from the group consisting of PMMA plastic, PC plastic, or PET-G plastic.

27. Combination of two covers according to claim 1, wherein the cover plates of each of the covers are above one another to run parallel to one another.

28. Building, in particular a greenhouse for the cultivation of plants, provided with a roof including a cover according to claim 1.

29. Combination comprising: a cover according to claim 1; and an object; wherein the cover covers the object; and wherein the object uses, absorbs, and converts solar radiation.

30. Combination according to claim 29, wherein the object includes at least one of an earth substrate and a plant.

31. Combination according to claim 29, wherein the object includes one or more solar cells of a type containing semiconductor material.

32. Combination according to claim 31, wherein the one or more solar cells are positioned in contact with one side of the cover sheet.

33. Combination according to claim 32, wherein the one or more solar cells have been applied to the cover sheet by deposition selected from the group consisting of vapor deposition, sputtering, CVD, and PVD.

34. Combination according to claim 29, wherein the object includes a solar collector.
